(19) United States
(12) Patent Application Publication
(10) Pub. No.: US 2010/0140558 A1
(43) Pub. Date: Jun. 10, 2010

(54) Apparatus and Method of Use for a Top-Down Directional Solidification System

(75) Inventors: David E. Carlson, Williamsburg, VA (US); Nathan G. Stoddard, Gettysburg, PA (US)

Correspondence Address: CAROL WILSON;BP AMERICA INC., MAIL CODE 5 EAST, 4101 WINFIELD ROAD, WARRENVILLE, IL, 60555, US

(73) Assignee: BP Corporation North America Inc., Warrenville, IL (US)

(21) Appl. No.: 12/629,190

(22) Filed: Dec. 2, 2009

Related U.S. Application Data
(60) Provisional application No. 61/121,048, filed on Dec. 9, 2008.

(51) Int. Cl. C30B 11/00; C01B 33/02; H01C 13/00

(52) U.S. Cl. 252/501.1; 117/206; 117/73; 423/348

(57) ABSTRACT

This invention relates to an apparatus and a method of use for a top-down directional solidification system, such as for casting solar grade silicon. The invention includes a vessel with a pressure relieving device to prevent pressure build up in the liquid as the solidification front advances from a downward direction. The invention also includes a drain to remove impurities, such as the concentration in the remaining liquid phase as casting nears completion.

This application claims the benefit of U.S. Provisional Application No. 61/121,048, filed Dec. 9, 2008. The entire disclosure of U.S. Provisional Application No. 61/121,048 is hereby incorporated by reference into this specification.

### BACKGROUND

1. Technical Field

This invention relates to an apparatus and a method of use for a top-down directional solidification system, such as for casting solar grade silicon.

2. Discussion of Related Art

Photovoltaic cells convert light into electric current. One of the most important features of a photovoltaic cell is its efficiency in converting light energy into electrical energy. Although photovoltaic cells can be fabricated from a variety of semiconductor materials, silicon is generally used because it is readily available at reasonable cost, and because it has a suitable balance of electrical, physical, and chemical properties for use in fabricating photovoltaic cells.

In a known procedure for the manufacture of photovoltaic cells, silicon feedstock is doped with a dopant having either a positive or negative conductivity type, melted, and then crystallized by pulling crystallized silicon out of a melt zone into ingots of monocrystalline silicon (via the Czochralski (CZ) or float zone (FZ) methods). For a FZ process, solid material is fed through a melting zone, melted upon entry into one side of the melting zone, and re-solidified on the other side of the melting zone, generally by contacting a seed crystal.

Recently, a new technique for producing monocrystalline or geometric multicrystalline material in a crucible solidification process (i.e. a cast-in-place or casting process) has been invented, as disclosed in U.S. patent application Nos.: 11/624,365 and 11/624,411, and published in U.S. Patent Application Publication Nos.: 20070169684A1 and 20070169685A1, filed Jan. 18, 2007. Casting processes for preparing multicrystalline silicon ingots are known in the art of photovoltaic technology. Briefly, in such processes, molten silicon is contained in a crucible, such as a fused silica crucible, and is cooled in a controlled manner to permit an upwards directional crystallization of the silicon contained therein. The block of cast crystalline silicon that results is generally cut into bricks having a cross-section that is the same as or close to the size of the wafer to be used for manufacturing a photovoltaic cell, and the bricks are sawn or otherwise cut into such wafers. Multicrystalline silicon produced in such manner is composed of crystal grains where, within the wafers made therefrom, the orientation of the grains relative to one another is effectively random. Monocrystalline or geometric multicrystalline silicon has specifically chosen grain orientations and (in the latter case) grain boundaries, and can be formed by the new casting techniques disclosed in the above-mentioned patent applications by melting in a crucible the solid silicon into liquid silicon in contact with a large seed layer that remains partially solid during the process and through which heat is extracted during solidification, all while remaining in the same crucible. As used herein, the term ‘seed layer’ refers to a crystal or group of crystals with desired crystal orientations that form a continuous layer. They can be made to conform to one side of a crucible for casting purposes.

In order to produce high quality cast ingots, several conditions should be met. Firstly, as much of the ingot as possible should have the desired crystallinity. If the ingot is intended to be monocrystalline, then the entire usable portion of the ingot should be monocrystalline, and likewise for geometric multicrystalline material. Secondly, the silicon should contain as few imperfections as possible. Imperfections can include individual impurities, agglomerates of impurities, intrinsic lattice defects and structural defects in the silicon lattice, such as dislocations and stacking faults. Many of these imperfections can cause a fast recombination of electrical charge carriers in a functioning photovoltaic cell made from crystalline silicon. This can cause a decrease in the efficiency of the cell.

Many years of development have resulted in a minimal amount of imperfections in well-grown CZ and FZ silicon. Dislocation free single crystals can be achieved by first growing a thin neck where all dislocations incorporated at the seed are allowed to grow out. The incorporation of inclusions and secondary phases (for example silicon nitride, silicon oxide or silicon carbide particles) is avoided by maintaining a counter-rotation of the seed crystal relative to the melt. Oxygen incorporation can be lessened using magnetic CZ techniques and minimized using FZ techniques as is known in the industry. Metallic impurities are generally minimized by being segregated to the tang end or left in the potscrap after the bode is brought to an end.

However, even with the above improvements in the CZ and FZ processes, there is a need and a desire to produce high purity crystalline silicon that is less expensive on a per volume basis, needs less capital investment in facilities, needs less space, and/or less complexity to operate, than known CZ and FZ processes. There is also a need and a desire to produce a high purity silicon with a reduced amount of impurities.

### SUMMARY

This invention relates to an apparatus and a method of use for a top-down directional solidification system, such as for casting solar grade silicon. A density of solid silicon is less than a density of liquid or molten silicon, such that solid silicon floats on top of liquid silicon. Absent an appropriate design, a crucible containing molten silicon cooled from a top surface splits or fractures the crucible as the solid silicon increases a pressure of the remaining molten silicon. A resulting spill of the remaining molten silicon may present significant safety, cost, and/or operational issues. The apparatus and method of this invention seek to reduce or prevent pressure under the solid silicon, according to one embodiment. The apparatus and method of this invention also seek to purify the silicon and/or reduce an amount of impurities, according to one embodiment. Desirably, but not necessarily, this invention excludes the use of rotation and minimizes or eliminates pulling action during the casting process.

According to one embodiment, this invention relates to a vessel for top-down directional solidification and purification suitable for casting silicon. The vessel includes a crucible, and a pressure equalizing device, such as to reduce pressure on the remaining liquid silicon as the solidification front advances from the top.

According to a second embodiment, this invention relates to a method for top-down directional solidification and purification suitable for casting silicon. The method includes the step of providing a molten feedstock in a vessel with a drain for removing impurities, the step of solidifying from a top direction by extracting heat through a top or at least the top side of the vessel. The method also includes the step of reducing impurities within the vessel through the drain.

According to a third embodiment, this invention relates to a high purity silicon ingot made by the method and/or apparatus described above.

### BRIEF DESCRIPTION OF THE DRAWINGS

The accompanying drawings, which are incorporated in and constitute a part of this specification, illustrate embodiments of the invention and, together with the description, serve to explain the features, advantages, and principles of the invention. In the drawings:

FIG. 1 illustrates a side cross sectional view of a top-down solidification vessel with an internal stand pipe, according to one embodiment;

FIG. 2 illustrates a side cross sectional view of a top-down solidification vessel with an external stand pipe, according to one embodiment;

FIG. 3 illustrates a side cross sectional view of a top-down solidification vessel with magnetic field coils, according to one embodiment;

FIG. 4 illustrates a side cross sectional view of a top-down solidification vessel with slideable walls, according to one embodiment; and

FIG. 5 illustrates a side cross sectional view of a top-down solidification vessel with a seed crystal, according to one embodiment.

### DETAILED DESCRIPTION

According to one embodiment, this invention includes the ability and process to purify refined metallurgical grade silicon into solar-grade silicon. The silicon ingots produced according to this invention can be high quality with low impurities. Top-down directional solidification can be used to direct impurities (silicon carbide particles and the like) to a bottom portion of the crucible, such as not to be incorporated into the finished cast silicon product.

The top-down directional solidification crucible may include a drain near the bottom of the crucible. The drain may be temperature controlled, such as to allow flow when desired and remain closed at other times. The drain may consist of a heated tube to equalize a pressure of the liquid silicon as the solidification front advances generally downward. The drain may also include one or more drain orifices in a bottom region of the crucible.

A directional solidification cycle for purification of the silicon may include draining a portion of liquid silicon through an orifice near the very bottom of the crucible to extract silicon carbide particles. Silicon carbide particles of greater than about 10 microns in diameter may sink to the bottom. Silicon carbide particles of less than about 10 microns may be pushed toward the bottom by the directional solidification front. During the draining process, the liquid silicon may be drained through an orifice elevated above the bottom of the crucible, such as to avoid extracting silicon carbide particles.

According to one embodiment, a top-down directional solidification system may include magnetic fields to prevent the solidified silicon from contact with the crucible walls, such as where the solidified silicon floats on the liquid silicon. Desirably, the magnetic fields perform or operate as a pressure equalization device, since the solidification does not extend to walls of the crucible. Accordingly, a heated tube or stand pipe to obtain pressure equilibration of the liquid silicon may not be needed in this embodiment. Also, the natural curvature of a magnetically levitated mass of silicon could be flattened out by the placement of a seed crystal from the top that would naturally float on the liquid. The seed crystal could initiate solidification by radiating directly to a cold wall, such as one located above the crucible.

Electromagnetic coils could be made out of boron nitride coated graphite, and could be powered independently. Desirably, the independent heater coils can be powered off after the solidification front passes by, such as the solidification front descends from above. Optionally, a mechanical ingot stabilizer could be included to prevent the solid ingot from bumping into the coils as the ingot floats on the liquid silicon.

In another embodiment, the heater coils can be replaced by a specially designed wall, where the wall moves relative to the liquid as the solidification front advances downward. The slideable wall can include a heating coil to ensure the solidified mass does not have close contact with the wall. This configuration or setup may advantageously be slightly less complicated.

Directional solidification of relatively impure silicon can be performed in a direction generally from a top to a bottom of a crucible. When most of the silicon has been solidified, the remaining high impurity liquid region near the bottom of the crucible can be drained through a temperature controlled tap or drain. The tap can then be closed, such as by local cooling. The remaining solidified silicon can be re-melted for purification by additional directional solidification or be directed into a casting chamber and/or a ribbon growth chamber, for example. According to one embodiment, at least a portion of the molten silicon displaced for the pressure equalization process may flow generally upward in a liquid column, such as from an orifice above a bottom of the crucible. While, a portion of impurity laden molten silicon can be removed or flow through the drain generally downward or opposite the flow for pressure equalization.

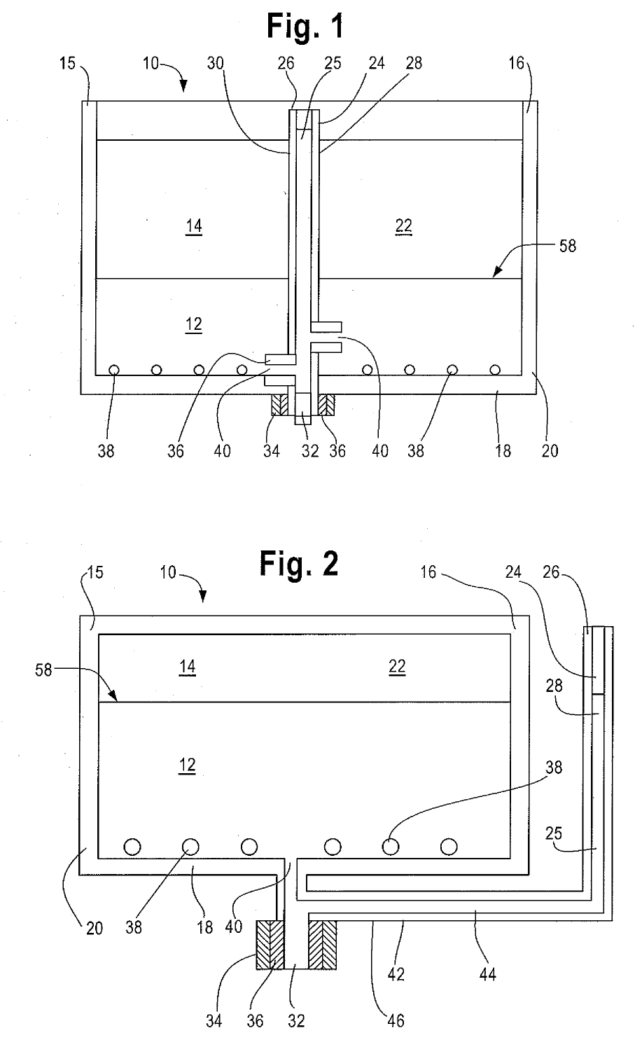

FIG. 1 shows a side sectional view of a vessel 10 with an internal configuration 30 for holding liquid silicon 12 and using top-down directional solidification to form solidified silicon 14, such as an ingot 22, according to one embodiment. The vessel 10 includes a top 16 and a bottom 18 with walls 20 in between and forming a crucible 15. The crucible 15 includes a volume, such as for containing the liquid or solid feedstock.

The vessel 10 includes a pressure equalizing or relieving device 24, such as a stand pipe 26 with a liquid column 25. The stand pipe 26 may include a heated tube 28 to keep the liquid column 25 from freezing or solidifying. The liquid column 25 may include any suitable height and may extend above a height of the original level of the molten silicon 12, such as pushed up by the pressure under the ingot 22. The standpipe 26 in FIG. 1 shows an internal configuration 30, such as with a generally vertical pipe disposed at any suitable location.

The vessel 10 may include a drain 32, such as with a heater 34 and/or a cooling coil 36 for controlling a flow of material through the drain 32. The flow through the drain 32 may remove and/or reduce impurities 38 from within the vessel 10. The stand pipe 26 may include one or more orifices 40, such as at or near the bottom 18. The stand pipe 26 may also include an orifice 40 above or off of the bottom 18. Desirably, impurities 38 may settle by gravity or be pushed downward by the solidification front 58 for removal.

FIG. 2 shows a side sectional view of a vessel 10 with an external configuration 42 for holding liquid silicon 12 and using top-down directional solidification to form solidified silicon 14, such as an ingot 22, according to one embodiment. The vessel 10 includes a top 16 and a bottom 18 with walls 20 in between and forming a crucible 15. The crucible 15 includes a volume, such as for containing the liquid or solid feedstock.

The vessel 10 includes a pressure equalizing or relieving device 24, such as a stand pipe 26 with a liquid column 25. The stand pipe 26 may include a heated tube 28 to keep the liquid column 25 from freezing or solidifying. The liquid column 25 may include any suitable height and may extend above a height of the original level of the molten silicon 12, such as pushed up by the pressure under the ingot 22. The standpipe 26 in FIG. 2 shows an external configuration 42, such as with a p-trap 44 formed by an at least partial u-shape 46 disposed at any suitable location, such as similar in shape to a manometer and/or a barometer, for example.

The vessel 10 may include a drain 32, such as with a heater 34 and/or a cooling coil 36 for controlling a flow of material through the drain 32. The flow through the drain 32 may remove and/or reduce impurities 38 from within the vessel 10. The stand pipe 26 may include one or more orifices 40, such as at or near the bottom 18. Desirably, impurities 38 may settle by gravity or be pushed downward by the solidification front 58 for removal.

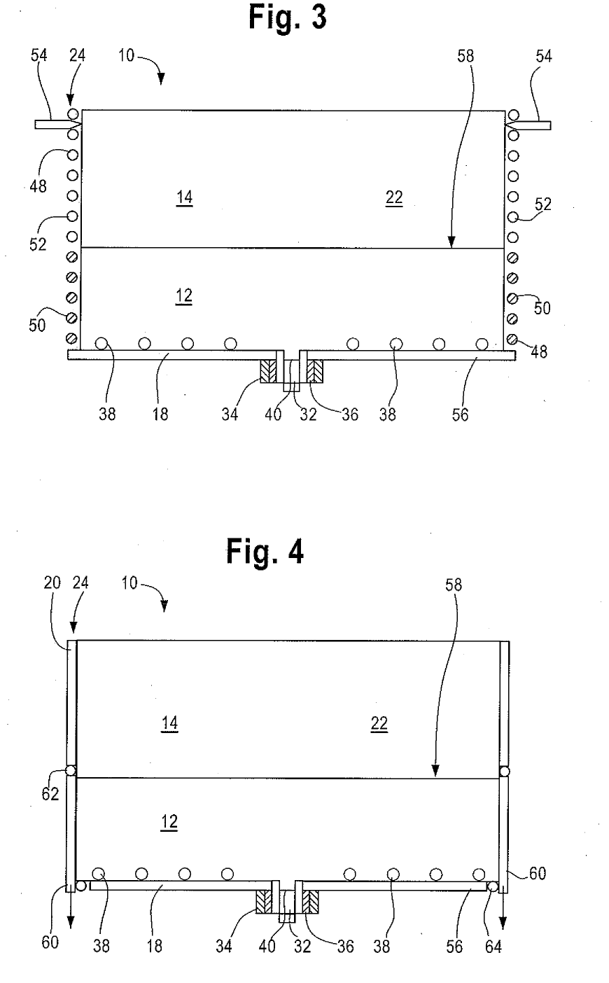

FIG. 3 shows a side sectional view of a vessel 10 with inductive magnetic field coils 48 for holding liquid silicon 12 and using top-down directional solidification to form solidified silicon 14, such as an ingot 22, according to one embodiment. The vessel 10 includes a bottom 18, such as a bottom plate 56. The bottom plate 56 may be constructed of any suitable material, such as silica, quartz, and/or the like.

The vessel 10 includes a pressure equalizing or relieving device 24, such as a series of magnetic field coils 48 with lines of magnetic flux extending from the magnetic field coils 48. The magnetic field coils 48 may also act as heating devices when electrified. The ingot 22 floats on the molten silicon 12, such as to allow upward displacement and reduce pressure under the ingot 22 from the advancing solidification front 58. Initially all magnetic field coils 48 can be electrified as energized coils 50. As the solidification front 58 advances downward, the energized coils at and/or above the solidification front 58 can be turned off as de-energized coils 52. One or more ingot stabilizers 54 can hold or support the ingot 22, such as to prevent the ingot 22 from contacting the magnetic field coils 48.

The vessel 10 may include a drain 32, such as with a heater 34 and/or a cooling coil 36 for controlling a flow of material through the drain 32. The flow through the drain 32 may remove and/or reduce impurities 38 from within the vessel 10. The drain 32 may include one or more orifices 40, such as at or near the bottom 18. Desirably, impurities 38 may settle by gravity or be pushed downward by the solidification front 58 for removal.

FIG. 4 shows a side sectional view of a vessel 10 with moveable, slideable, or sliding walls 60 for holding liquid silicon 12 and using top-down directional solidification to form solidified silicon 14, such as an ingot 22, according to one embodiment. The vessel 10 includes walls 20 and a bottom 18, such as a bottom plate 56. The bottom plate 56 may be constructed of any suitable material, such as silica, quartz, and/or the like.

The vessel 10 includes a pressure equalizing or relieving device 24, such as sliding walls 60. The sliding walls 60 may be constructed of any suitable material, such as silica, quartz, and/or the like. The sliding walls 60 may include a wall heater 62, such as generally disposed and moving along or with the solidification front 58 and energized during casting and solidification. The sliding wall 60 may also include a sealing coil 64, such as between the sliding wall 60 and the bottom plate 56 and energized during casting and solidification while remaining at least generally stationary.

The vessel 10 may include a drain 32, such as with a heater 34 and/or a cooling coil 36 for controlling a flow of material through the drain 32. The flow through the drain 32 may remove and/or reduce impurities 38 from within the vessel 10. The drain 32 may include one or more orifices 40, such as at or near the bottom 18. Desirably, impurities 38 may settle by gravity or be pushed downward by the solidification front 58 for removal.

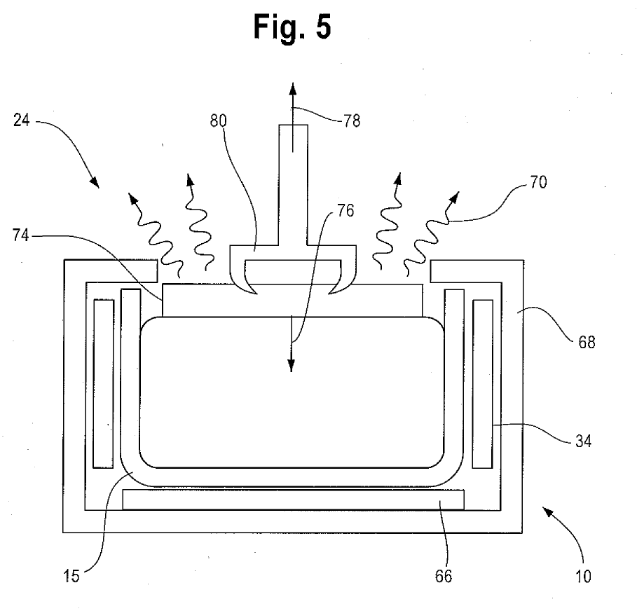

FIG. 5 shows a side cross sectional view of a top-down solidification vessel 10 with a seed crystal 74, according to one embodiment. The vessel 10 includes a crucible 15 on a support plate 66 with heaters 34 and insulation 68. The vessel 10 also includes a pressure equalization device 24. The direction of the solidification front as shown by arrow 76 may occur with radiative cooling, such as through the seed crystal 74 shown by arrow 70. Optionally, a heat sink (not shown) provides additional cooling by radiation, convection, and/or conduction, such as through a seed holder 80. The seed holder 80 may include two or more tines or fingers, such as to grab or dig into the seed crystal 74. Also optionally, the seed holder 80 may further include a pulling mechanism or device (not shown) and/or a rotating mechanism or device (not shown). The pulling may be in the direction shown by the arrow 78. Desirably, the pulling may be done slowly, such as to substantially match a growth rate of the solidification front, for example.

Moreover, although casting of silicon has been described herein, other semiconductor materials and nonmetallic crystalline materials may be cast without departing from the scope and spirit of the invention. For example, the inventors have contemplated casting of other materials consistent with embodiments of the invention, such as germanium, gallium arsenide, silicon germanium, aluminum oxide (including its single crystal form of sapphire), gallium nitride, zinc oxide, zinc sulfide, gallium indium arsenide, indium antimonide, germanium, yttrium barium oxides, lanthanide oxides, magnesium oxide, calcium oxide, and other semiconductors, oxides, and intermetallics with a liquid phase. In addition, a number of other group III-V or group II-VI materials, as well as metals and alloys, could be cast according to embodiments of the present invention.

Cast silicon includes multicrystalline silicon, near multicrystalline silicon, geometric multicrystalline silicon, and/or monocrystalline silicon. Multicrystalline silicon refers to crystalline silicon having about a centimeter scale grain size distribution, with multiple randomly oriented crystals located within a body of multicrystalline silicon.

Geometric multicrystalline silicon or geometrically ordered multicrystalline silicon refers to crystalline silicon having a nonrandom ordered centimeter scale grain size distribution, with multiple ordered crystals located within a body of multicrystalline silicon. The geometric multicrystalline silicon may include grains typically having an average about 0.5 centimeters to about 5 centimeters in size and a grain orientation within a body of geometric multicrystalline silicon can be controlled according to predetermined orientations, such as using a combination of suitable seed crystals.

Polycrystalline silicon refers to crystalline silicon with micrometer to millimeter scale grain size and multiple grain orientations located within a given body of crystalline silicon. Polycrystalline silicon may include grains typically having an average of about submicron to about micron in size (e.g., individual grains are not visible to the naked eye) and a grain orientation distributed randomly throughout.

Monocrystalline silicon refers to crystalline silicon with very few grain boundaries since the material has generally and/or substantially the same crystal orientation. Monocrystalline material may be formed with one or more seed crystals, such as a piece of crystalline material brought in contact with liquid silicon during solidification to set the crystal growth. Near monocrystalline silicon refers to generally crystalline silicon with more grain boundaries than monocrystalline silicon but generally substantially fewer than multicrystalline silicon.

According to one embodiment, this invention may include a vessel for top-down directional solidification and purification suitable for casting silicon. The vessel may include a crucible and a pressure equalizing device.

Top-down directional solidification broadly refers to methods, process, techniques, and the like, where a solidification front or solid-liquid interface advances in a generally downward direction, such as from above. Desirably, a solid block of silicon forms on or floats on a pool of molten silicon as assisted and/or aided by the density or buoyancy differences of the solid and the liquid, such as where solid silicon rides on top of molten silicon. The solidification front may advance in a generally uniform or consistent manner, such as without significant variations in a thickness of the solid with respect to a time and/or a location.

Purification broadly refers to reducing, removing, sequestering, and/or neutralizing impurities or undesired particles, compounds, atoms, and/or the like. Solidification and/or crystallization can be purification processes when properly performed or conducted. The impurities may accumulate in a remaining portion of the liquid phase as a mass or size of the solid phase increases. Impurities in silicon broadly include carbon, silicon carbide, silicon nitride, oxygen, metals, and/or substances which generally reduce an efficiency of a solar cell or a solar module. The impurities may include any suitable size and/or shape, such as less than about 10 microns (micrometers) and/or greater than about 10 microns. Generally, particles denser than silicon and greater than about 10 microns may sink in molten silicon. Generally, particles less than about 10 microns of any density may be suspended and/or float in molten silicon.

A vessel broadly includes a container for holding something, such as silicon feedstock. The vessel of this invention may include any suitable size and/or shape. The vessel may include one or more walls or sides, such as forming a generally circular shape, a generally elliptical shape, a generally triangular shape, a generally square shape, a generally rectangular shape, a generally hexagonal shape, a generally octagonal shape, and/or any other suitable shape or configuration. Generally, square ingots and/or rectangular ingots may result in a higher product to scrap ratio as less irregular edges are trimmed away.

The vessel may include any suitable number of walls, such as about 1, about 3, about 4, about 6, about 8, and/or the like. The walls may include straight and/or arcuate sections with any suitable angle or orientation, such as generally vertical, tapered inwards, tapered outwards and/or the like.

The vessel can include any suitable size, such as at least about 0.1 meters cubed, at least about 0.2 meters cubed, at least about 0.5 meters cubed, at least about 1 meter cubed, and/or the like. The vessel can be formed and/or bounded by the bottom and the walls, for example. The vessel can include any suitable diameter, length, width, and/or height. According to one embodiment, a ratio of height to length can be about 0.5:1.0, about 1.0:1.0, about 1.0:0.5 and/or any other suitable proportion.

The width of the vessel may include any suitable distance, such as about 20 centimeters to about 200 centimeters, about 50 centimeters to about 120 centimeters, about 50 centimeters to about 70 centimeters, about 67 centimeters, and/or the like. The height of the vessel may include any suitable distance, such as about 5 centimeters to about 100 centimeters, about 15 centimeters to about 50 centimeters, about 30 centimeters to about 35 centimeters, about 32.5 centimeters, and/or the like.

The vessel can hold any suitable amount of liquid silicon and/or solid silicon, such as at least about 100 kilograms, at least about 200 kilograms, at least about 500 kilograms, at least about 750 kilograms, at least about 1000 kilograms, and/or the like. Desirably, the vessel can withstand exposure to elevated temperatures, such as at least about 500 degrees Celsius, at least about 750 degrees Celsius, at least about 1000 degrees Celsius, at least about 1250 degrees Celsius, at least about 1412 degrees Celsius (melting point of silicon), at least about 1500 degrees Celsius, and/or the like.

A crucible broadly may include a vessel of refractory material or the like used for melting, calcining, and/or other processing of a substance that requires a high degree of heat. Desirably, but not necessarily, the crucible may include a generally square shape, a generally rectangular shape, a generally circular shape, and/or the like. Embodiments with rotational mechanisms may include crucibles with a generally circular shape, a generally hexagonal shape, a generally polygonal shape, and/or the like.

The vessel may include or be made of any suitable material or substance, such as graphite, silicon carbide, silicon nitride, silica, fused silica, quartz, high temperature ceramic, aluminum oxide, aluminum nitride, aluminum silicate, boron nitride, zirconium phosphate, zirconium diboride, hafnium diboride, and/or the like. Desirably, the vessel may include materials of construction compatible with molten silicon, such as to not contaminate the feedstock and/or the product.

The vessel may be a single-use design, such as generally fractures upon solidification of the ingot, or the vessel may be a multiple-use design, such as generally does not fracture upon solidification of the ingot. The vessel may include additional spouts, nozzles, instrument ports, vents, addition ports, doping devices, and/or the like to synergistically compliment the casting process.

Desirably, the vessel includes a monolithic and/or integral structure, construction, and/or fabrication, such as without joints and/or seams. In the alternative, the vessel includes multiple components or pieces assembled together, such as by mechanical fasteners.

The vessel may be used in any portion or part of the casting process, such as in a melting step, in a holding or accumulating step, in a purification step, and/or in a solidification step. According to one embodiment, the same vessel is used for all steps in a casting process. In the alternative, separate vessels may be used for the individual steps of the casting process, such as with the pouring or transferring of molten feedstock between the vessels.

The pressure equalizing device broadly may include any suitable mechanism or structure to reduce and/or prevent a pressure increase in the vessel as the solidification process occurs. A mass of solid silicon occupies and/or takes up more space than the same mass of liquid silicon. Similar to water and unlike most other substances or materials, solid silicon is less dense than liquid silicon. Conventional crucibles for casting silicon have a closed bottom. The closed bottom of conventional crucibles does not allow pressure relief as the solid advances from the top. The remaining liquid silicon is substantially incompressible, so the pressure at the bottom of the closed bottom crucible increases until failure or fracture of the ceramic material. Or the liquid silicon disturbs or disrupts the solidification of the ingot, such as by popping the ingot over on one end to reduce the pressure.

According to one embodiment, the pressure equalizing device comprises a temperature controlled drain, such as a tube or a pipe with a heat source switchable between an on and off mode or position. The on mode heats the contents of the pipe to melt at least a portion of the silicon, such as to reduce pressure under the solid. The off mode passively cools the pipe to solidify or freeze at least a portion of the silicon, such as to stop and/or reduce flow through the pipe. In the alternative, the pressure equalizing device includes an active cooling mechanism, such as tubing with cooling water flowing through it. The cooling mechanism may increase the freezing within the pressure equalizing device.

The pressure equalizing device may include a stand pipe, such as for equalizing a liquid pressure below a mass of solidified silicon. A stand pipe broadly refers to a vertical pipe or reservoir used to secure a uniform pressure in a fluid or liquid system or device. Desirably, the stand pipe uses hydrostatic head or forces to balance or offset the pressure from the solid. A level of molten silicon within the standpipe increases to relieve more pressure as the solidification front advances. Put another way, the increasing solid displaces more of the liquid silicon into the standpipe. Desirably, the standpipe allows pressure equalization without excess loss of molten silicon from the vessel. Using the stand pipe to reduce impurities is possible, but the relatively small volume of flow with the stand pipe may not be as effective as desired for reducing impurities.

The standpipe may include a heat source, such as a resistance heater. The standpipe may also include insulation, such as to at least partially thermally isolate the standpipe from the surroundings.

The stand pipe may be located in any suitable location with respect to the vessel. The stand pipe may be at least generally centrally disposed with respect to the vessel. In the alternative the stand pipe may be offset and/or off centered with respect to the vessel. The stand pipe may be disposed or located in a corner of the vessel. The stand pipe may be separate or distinct from the vessel or the crucible, such as including separate pieces and mechanical connectors. In the alternative the stand pipe may be integral or incorporated into the vessel or the crucible, such as cast during the same process. In any event, the standpipe can have heating elements to be able to maintain liquid silicon throughout its volume in order to prevent clogging or pressure build-up.

The stand pipe may include one or more apertures, orifices, holes, ports, openings, and/or the like. The openings may be at any suitable location and/or height. The openings may be located at the inside bottom surface of the crucible. In the alternative, the openings may be above the inside bottom surface of the crucible.

The stand pipe may include a p-trap design, such as with a first leg and second longer leg for allowing a liquid column height to change within based on pressure. The p-trap may also generally and broadly be referred to as a j-shape design or a u-shape design. The p-trap may also include a similar shape to a manometer and/or a barometer, for example.

According to one embodiment, the pressure equalizing device includes a standpipe for equalizing a liquid pressure below a mass of solidified silicon. In the alternative, the stand pipe includes a heated tube external to the crucible with a p-trap. According to one further embodiment the standpipe includes a heated tube internal to the crucible. According to a still further embodiment, the stand pipe includes one or more orifices disposed on or above a bottom of the crucible.

The pressure equalizing device may include one or more magnetic field coils, such as to maintain a mass of solidified silicon on a mass of molten silicon. Desirably, the magnetic field coils can keep a gap around the solid silicon from the wall of the vessel to prevent pressure build up. The magnetic coils at least generally encircle or can be peripherally disposed around and/or along a perimeter of the vessel. The magnetic field coils may include a conductor, such as to emit a magnetic field when energized and affect the silicon. Desirably, but not necessarily, the one or more magnetic field coils comprise boron nitride, barium oxide or silicon carbide coated graphite and/or any other suitable material.

According to one embodiment, the magnetic field coils may include a generally fixed position or location. Multiple magnetic field coils may be switched or turned on and/or off corresponding to a position or a location of the solidification front, such as switched off once the solidification front passes. In the alternative, the magnetic field coils may be movable, such as to follow a general location or a position of the solidification front.

The vessel may further include one or more ingot stabilizers, such as to prevent the solid ingot from bumping, touching, or contacting the walls of the crucible or the heating coils. The ingot stabilizers may include any suitable design. According to one embodiment, the ingot stabilizer includes two or more elongated members disposed at least generally opposite each other for contacting a portion of solid silicon, such as a top most portion of the solid silicon. Desirably, but not necessarily, the ingot stabilizers may be used in combination with the magnetic field coils. The ingot stabilizers may be made or constructed of any of the materials described above for the crucible. Additional suitable materials may include graphite, alumina, steel, stainless steel, alloy, nickel alloy, and/or the like.

According to one embodiment, the pressure equalization device and/or the crucible includes sliding walls movable with respect to the solidification front, such as in a generally downward direction. The sliding walls also be referred to as retaining walls and may include any suitable material, such as silica, fused silica, quartz, and/or the like. Desirably, but not necessarily, the sliding walls may include a wall heating coil, such as providing heat input at or near the solidification front and preventing solidification to the sliding walls.

The sliding walls may be in combination with the bottom of the crucible with and/or by one or more sealing coils, such as resistance heaters. Optionally, the sliding wall includes a section, a portion, or a piece of the wall aligned with the solidified silicon. In the alternative, the sliding wall does not include a section, a portion, or a piece of the wall aligned with the solidified silicon, such as the ingot may be open and/or exposed to the rest of the furnace or casting station.

The sliding wall may be moved downward and/or upward with any suitable actuation device or process, such as manually, hydraulically, electrically, pneumatically, mechanically, and/or the like. The sliding walls may advance as a function or in relation to the solidification rate and/or solid-liquid interface, for example.

According to one embodiment, this invention includes drain to remove impurities. The drain may be located at any suitable location, such as generally centrally located in the crucible and/or off set from the crucible. Desirably, the drain is located at and/or near the bottom of the crucible. The drain may include heater coils and/or cooling coils, such as for controlling a temperature of the drain assembly to regulate flow. The drain may be integral to the pressure equalizing device and/or may be separate, distinct, or independent. Desirably, the drain allows molten silicon to be removed from the vessel and may in doing so relieve pressure. Using the drain to relieve pressure may reduce the volume of molten silicon in the vessel by more than desired.

According to one embodiment the vessel may include at least one seed crystal. The seed crystal may contact the molten feedstock from above and/or be disposed with respect to an interior surface of the vessel, such as on one or more sides. Optionally, the seed crystal may include one generally uniform orientation and/or may include a tiled arrangement of differing orientations, for example. The seed crystal may be used with any embodiment of the pressure equalization device, such as the internal stand pipe, external stand pipe, floating ingot, sliding walls, and/or the like.

The vessel and/or related items may exclude devices and/or functions to allow and/or perform rotation of the seed crystal, the feedstock, the apparatus, and/or the like. The vessel and/or related items may exclude devices and/or functions to allow and/or perform drawing or pulling of the seed crystal, the feedstock, the apparatus, and/or the like. In the alternative, the vessel and/or related items may include devices and/or functions to allow and/or perform rotation of the seed crystal, the feedstock, the apparatus, and/or the like. In the alternative, the vessel and/or related items may include devices and/or functions to allow and/or perform drawing or pulling of the seed crystal, the feedstock, the apparatus, and/or the like. The rotating and/or pulling may be at any suitable rate, such as proportional to the rate of solidification and/or heat removal.

As used herein the terms “having”, “comprising”, and “including” are open and inclusive expressions. Alternately, the term “consisting” is a closed and exclusive expression. Should any ambiguity exist in construing any term in the claims or the specification, the intent of the drafter is toward open and inclusive expressions.

Regarding an order, number, sequence and/or limit of repetition for steps in a method or process, the drafter intends no implied order, number, sequence and/or limit of repetition for the steps to the scope of the invention, unless explicitly provided.

According to one embodiment, this invention may include a method for top-down directional solidification and purification suitable for casting silicon. The method may include the step of providing a molten feedstock in a vessel with a pressure equalizing device. Optionally, the method may include the step of relieving a pressure build up under or below a solid silicon body or ingot. The method may include the step of solidifying at least a portion of the molten feedstock from a top direction by extracting heat through a top and/or at least one side of the vessel. Desirably, the heat may be extracted from all sides of the vessel and the top, while at least a portion of the bottom optionally remains heated. In the alternative, some heat may be extracted through the bottom. The method may further include reducing impurities within the vessel through a drain.

Relieving pressure broadly refers to preventing an increase in pressure below the solid as compared to a pressure above the solid. The relieving pressure may include expanding a volume for the liquid, raising or displacing the solid, maintaining a gap around the solid, and/or the like.

Solidifying broadly refers to turning a substance or material into a solid form with a phase change, such as generally not a liquid or a gas. Desirably, the solidifying includes crystallization, such as generally a chemical element, a compound, and/or a mixture with a regularly repeating internal arrangement of atoms and external plane faces. The solidifying may form multicrystalline silicon, near multicrystalline silicon, geometric multicrystalline silicon, and/or monocrystalline silicon.

Extracting heat and/or removing temperature may be completed or accomplished by any suitable mechanism or technique, such as by convection, conduction, radiation, and/or the like. Extracting heat may be an active process, such as by flowing water in a cooling coil or blowing a cool gas across a hot surface. In the alternative, extracting heat may be a passive process, such was without additional devices. Desirably, radiation provides at least a majority of heat extraction and/or removal.

Generally solidification may occur by lowering and/or reducing an internal energy and/or enthalpy of a substance, such as to remove superheat and a heat of fusion from the liquid or molten state. Solidification may further include subcooling, such as below the freezing point of a material. Desirably, subcooling includes reaching ambient conditions, such as about 20 degrees Celsius.

The method may also include the step of melting the feedstock in the first volume, such as with heaters. According to one embodiment, this method excludes the step of rotating a portion of the apparatus and/or excludes the step of pulling the crystal. According to one embodiment, the method may include placing one or more seed crystals and/or layers within the vessel and/or in contact with at least a portion of the molten feedstock. The method may include melting at least a portion of the seed crystal and orienting the solidifying feedstock with the seed crystal.

According to one embodiment, the step of extracting heat may include removing at least a portion of the heat through the seed crystal, such as by conduction to a heat sink or cooling water line. The heat flux through the seed crystal desirably can be controlled (increased and/or decreased), such as during different times or steps the crystallization process. The seed crystal may include any suitable material, such as monocrystalline silicon, near monocrystalline silicon, multicrystalline silicon, and/or the like. Additionally and/or optionally, radiation from the seed crystal to a cooler surface or heat sink may also be a suitable method to extract heat.

Configurations of direct physical contact between the seed crystal and the heat sink are within the scope of this invention. In the alternative, configurations of indirect contact (space) between the seed crystal and the heat sink are within the scope of this invention. Embodiments without a heat sink are also within the scope of this invention.

According to one embodiment, the seed crystal may include a shaped geometry adapted for cooling and initializing crystal growth. The seed crystal may include any suitable size and/or shape. Desirably, the seed crystal includes a cross sectional area for contacting the molten silicon corresponding to a cross sectional area of the crucible, such as at least about 10 percent of the crucible, at least about 25 percent of the crucible, at least about 50 percent of the crucible, at least about 75 percent of the crucible, and/or the like. The seed crystal desirably thermally contacts a heat sink, such as for solidifying the molten silicon.

The step of reducing impurities may include flowing the impurities through the drain in or above a bottom of the vessel. The impurities may include silicon carbide, silicon nitride, and/or the like. The impurities may include particles greater than about 10 microns. The step of reducing may also include activating a heater to melt at least a portion a solid feedstock, such as within and/or near the drain. The heater coils may be generally concentric, such as disposed around cooling coils. In the alternative, the cooling coils can be disposed around heating coils.

According to one embodiment, the method also includes the step of equalizing a liquid pressure below a mass of solidified silicon, such as by flowing a portion of molten silicon in or up a standpipe. In the alternative, the flowing may also include down, such as if a p-trap or u-shape configuration is used.

The method may also include the step of contacting a top surface of the molten feedstock with a seed crystal. Desirably, the method may exclude actions of rotating, such as turning the seed crystal and/or a portion of the apparatus. Also desirably, the method may exclude actions of pulling upward and/or drawing the solid away our out of the liquid.

According to one embodiment, this invention may include a method for casting silicon. The method may include any or all of the steps discussed above and the step of maintaining a mass of solidified silicon on a mass of molten silicon with while preventing liquid leakage (to prevent pressure under the solidified silicon) using one or more magnetic field coils. Liquid leakage broadly includes a gap or space between and/or around a perimeter of the solidified silicon or ingot. The gap also provides separation form the wall of the crucible or the vessel. The liquid leakage prevents pressure build up by allowing floating and/or displacing of the ingot.

The method may further include the step of holding or isolating the mass of solidified silicon with an ingot stabilizer, such as with two or more elongated members. According to one embodiment, this invention may include the step of providing metallurgical grade silicon to the vessel and the finished product may include solar grade silicon and/or high purity silicon.

Desirably, but not necessarily, the method may include a step where the magnetic field coils deactivate after a solidification interface passes, such as where additional lower magnetic field coils remain or become energized.

The method may also include a step of moving slideable walls down in tandem with the advance of a solidification front, such as to effectively vary a volume of the crucible under the molten silicon mass and reduce or relieve pressure. The method may also include the step of equalizing or relieving a liquid pressure below a mass of solidified silicon, by displacing generally upward the mass of solidified silicon.

According to one embodiment, this invention includes a high purity silicon ingot made by the apparatuses and/or the methods described above. The ingot may include primarily silicon selected from the group consisting of multicrystalline silicon, monocrystalline silicon, near monocrystalline silicon, geometric multicrystalline silicon, and/or the like. The ingot may further be substantially free from radially distributed defects, such as made without the use of rotational processes.

The ingot of this invention may include any suitable level of reduced impurities. Impurities broadly include carbon, silicon carbide, silicon nitride, oxygen, other metals, and/or substances which generally reduce an efficiency of a solar cell or a solar module. The ingot may include a carbon concentration of about 2×10¹⁶ atoms/centimeter cubed to about 5×10¹⁷ atoms/centimeter cubed, an oxygen concentration not exceeding 7×10¹⁷ atoms/centimeter cubed, and a nitrogen concentration of at least 1×10¹⁵ atoms/centimeter cubed.

It will be apparent to those skilled in the art that various modifications and variations can be made in the disclosed structures and methods without departing from the scope or spirit of the invention. Particularly, descriptions of any one embodiment can be freely combined with descriptions or other embodiments to result in combinations and/or variations of two or more elements or limitations. Other embodiments of the invention will be apparent to those skilled in the art from consideration of the specification and practice of the invention disclosed herein. It is intended that the specification be considered exemplary only, with a true scope and spirit of the invention being indicated by the following claims.

What is claimed is:

1. A vessel for top-down directional solidification and purification suitable for casting silicon, the vessel comprising:
a crucible; and
a pressure equalizing device.

2. The vessel of claim 1, wherein the pressure equalizing device comprises a standpipe for equalizing a liquid pressure below a mass of solidified silicon.

3. The vessel of claim 2, wherein the standpipe comprises a heated tube internal to the crucible.

4. The vessel of claim 3, wherein the standpipe comprises one or more orifices disposed on or above a bottom of the crucible.

5. The vessel of claim 2, wherein the standpipe comprises a heated tube external to the crucible with a p-trap.

6. The vessel of claim 1, wherein the vessel comprises fused silica.

7. The vessel of claim 1, further comprising one or more magnetic field coils to maintain a mass of solidified silicon on a mass of molten silicon.

8. The vessel of claim 7, wherein the one or more magnetic field coils comprise boron nitride coated graphite.

9. The vessel of claim 7, further comprising an ingot stabilizer.

10. The vessel of claim 1, wherein the crucible comprises sliding walls movable with respect to a solidification front.

11. The vessel of claim 10, wherein the sliding walls comprise silica.

12. The vessel of claim 1, further comprising a drain to remove impurities.

13. A method for top-down directional solidification and purification suitable for casting silicon, the method comprising:
providing a molten feedstock in a vessel with a pressure equalizing device;
solidifying from a top direction by extracting heat through a top or at least one side of the vessel; and
reducing impurities within the vessel through a drain.

14. The method of claim 13, wherein the reducing comprises flowing the impurities through the drain in or above a bottom of the vessel.

15. The method of claim 13, wherein the reducing comprises activating a heater to melt at least a portion a solid feedstock.

16. The method of claim 13, wherein the impurities comprise silicon carbide or silicon nitride.

17. The method of claim 16 wherein the impurities comprise particles greater than about 10 microns.

18. The method of claim 13, further comprising equalizing a liquid pressure below a mass of solidified silicon.

19. The method of claim 18, wherein the equalizing includes flowing molten silicon in or up a standpipe.

20. The method of claim 13, further comprising contacting a top surface of the molten feedstock with a seed crystal.

21. The method of claim 20, wherein the contacting excludes actions of rotating.

22. The method of claim 20, wherein the contacting excludes actions of pulling upward.

23. The method of claim 20, wherein the extracting heat includes removing at least a portion of the heat through the seed crystal.

24. The method of claim 20, wherein the seed crystal comprises a shaped geometry adapted for cooling and initializing crystal growth.

25. The method of claim 13, further comprising maintaining a mass of solidified silicon on a mass of molten silicon with while preventing liquid leakage using one or more magnetic field coils.

26. The method of claim 25, further comprising holding the mass of solidified silicon with an ingot stabilizer.

27. The method of claim 25, wherein magnetic field coils deactivate after a solidification interface passes.

28. The method of claim 13, further comprising moving slideable walls down in tandem with the advance of a solidification front.

29. The method of claim 28, further comprising equalizing a liquid pressure below a mass of solidified silicon, by allowing generally upward displacement of the mass of solidified silicon.

30. A high purity silicon ingot made by the method of claim 13.

31. The ingot of claim 30, wherein the ingot comprises primarily silicon selected from the group consisting of multicrystalline silicon, monocrystalline silicon, near monocrystalline silicon, geometric multicrystalline silicon, and combinations thereof.

32. The ingot of claim 30, wherein the ingot is substantially free from radially distributed defects.

33. The ingot of claim 30, wherein the ingot comprises a carbon concentration of about 2×10¹⁶ atoms/centimeter cubed to about 5×10¹⁷ atoms/centimeter cubed, an oxygen concentration not exceeding 7×10¹⁷ atoms/centimeter cubed, and a nitrogen concentration of at least 1×10¹⁵ atoms/centimeter cubed.
